(19) United States
(12) Patent Application Publication
(10) Pub. No.: US 2023/0367920 A1
(43) Pub. Date: Nov. 16, 2023

(54) SYSTEM AND METHOD OF FOUNDATION REPAIR DIAGNOSTICS AND REMEDIATION DESIGN

(71) Applicant: Arizona Foundation Solutions, LLC, Phoenix, AZ (US)

(72) Inventor: Robert K. BROWN, Phoenix, AZ (US)

(21) Appl. No.: 18/316,806

(22) Filed: May 12, 2023

Related U.S. Application Data
(60) Provisional application No. 63/341,977, filed on May 13, 2022.

(51) Int. Cl. G06F 30/13; G06V 20/10; G06V 20/17

(52) U.S. Cl. CPC G06F 30/13; G06V 20/17; G06V 20/188

(57) ABSTRACT

A method for creating remedial geotechnical engineering plans for a structure includes receiving, at a recommendation design platform: first and second data from a first and second visit, respectively, to the structure and custom third-party input. The first and second data includes manometer readings providing elevation measurements. The method also includes constructing first and second topographical maps of the floor of the structure using the first and second elevation measurements, respectively, and comparing the first and second elevation measurements to determine soil movement over time. The recommendation design platform creates proposed remedial geotechnical engineering plans based on the determined soil movement over time (and other data of the first and second data). Modifications from a licensed engineer are received at the recommendation design platform to create sealed remedial geotechnical engineering plans.

### RELATED APPLICATION

This application claims the benefit of U.S. provisional Pat. application 63/341,977, filed May 13, 2022, titled “System and Method of Foundation Repair Diagnostics and Remediation Design,” the entirety of the disclosure of which is hereby incorporated by this reference.

### TECHNICAL FIELD

This document relates to systems and methods for foundation repair diagnostics and remediation design.

### BACKGROUND

Structures (such as homes, offices, buildings, or other types of structures) typically include a foundation to give the structure strength and stability. Over time, however, as conditions of a site on which the structure is built change, foundations can become damaged or otherwise need repair. Known approaches to foundation repair have drawbacks. For example, in some instances, foundation repair services are sold by a salesperson without adequate knowledge of the repair needed (e.g., due to lack of understanding of conditions at the site), leading to repairs that lack in quality or applicability. In other instances, an engineer-driven process may result in better-quality recommendations for foundation repair services, but the cost of the process can be prohibitive.

### SUMMARY

Aspects of this disclosure relate to a method for creating remedial geotechnical engineering plans for a structure with a recommendation design platform. In some embodiments, the method includes receiving first data at the recommendation design platform from a first visit by a site technician to the structure. In some embodiments, the first data includes first manometer readings providing first elevation measurements for a floor of the structure, first moisture observations around a foundation of the structure, proximity of vegetation to the structure at a time of the first visit, and evidence of cracks in the structure at the time of the first visit. In some embodiments, the method includes receiving second data at the recommendation design platform from a second visit to the structure at least 1 year after the first visit. In some embodiments, the second data includes second manometer readings providing second elevation measurements for the floor of the structure, second moisture observations around the foundation of the structure, proximity of vegetation to the structure at a time of the second visit, and evidence of cracks in the structure at the time of the second visit. In some embodiments, the method includes receiving custom third-party input at the recommendation design platform. In some embodiments, the custom third-party input includes an aerial site image, historical rainfall information, a deflection analysis, information from the Nuclear Regulatory Commission or the Post-Tensioning Institute, and drone-captured lidar point cloud data. In some embodiments, the method includes constructing a first topographical map of the floor of the structure using the first elevation measurements, constructing a second topographical map of the floor of the structure using the second elevation measurements, comparing, by the recommendation design platform, the first elevation measurements for the floor of the structure and the second elevation measurements for the floor of the structure to determine soil movement over time, and creating, by the recommendation design platform, proposed remedial geotechnical engineering plans for the structure based on the determined soil movement over time, the evidence of cracks in the structure at the time of the first visit and at the time of the second visit, and the first and second moisture observations around the foundation of the structure. In some embodiments, the method includes receiving, at the recommendation design platform, modifications to the proposed remedial geotechnical engineering plans from a licensed engineer to create sealed remedial geotechnical engineering plans for the structure.

Particular implementations may include one or more of the following features. In some embodiments, the second visit to the structure is at least 5 years after the first visit. In some embodiments, the first topographical map of the floor of the structure is a two-dimensional topographical map. In some embodiments, the method also includes constructing a three-dimensional topographical map of the floor of the structure using the first elevation measurements. In some embodiments, the first topographical map of the floor of the structure is a three-dimensional topographical map. In some embodiments, the method also includes displaying a floor plan of the structure overlaid on the first topographical map of the floor of the structure. In some embodiments, the method also includes displaying a marker on the floor plan indicating a location of the evidence of cracks in the structure at the time of the first visit.

Aspects of this disclosure relate to a method for creating remedial geotechnical engineering plans for a structure with a recommendation design platform. In some embodiments, the method includes receiving first data at the recommendation design platform from a first visit by a site technician to the structure, wherein the first data includes first elevation measurements for a floor of the structure. In some embodiments, the method includes receiving second data at the recommendation design platform from a second visit to the structure after the first visit, wherein the second data includes second elevation measurements for a floor of the structure. In some embodiments, the method includes receiving custom third-party input at the recommendation design platform, comparing, by the recommendation design platform, the first elevation measurements for the floor of the structure and the second elevation measurements for the floor of the structure to determine soil movement over time, and creating, by the recommendation design platform, proposed remedial geotechnical engineering plans for the structure based on the determined soil movement over time, evidence of cracks in the structure, and moisture observations around a foundation of the structure. In some embodiments, the method includes receiving, at the recommendation design platform, modifications to the proposed remedial geotechnical engineering plans from a licensed engineer to create sealed remedial geotechnical engineering plans for the structure.

Particular implementations may include one or more of the following features. In some embodiments, the second visit to the structure is at least 1 year after the first visit. In some embodiments, the second visit to the structure is at least 5 years after the first visit. In some embodiments, the method also includes constructing a first topographical map of the floor of the structure using the first elevation measurements and constructing a second topographical map of the floor of the structure using the second elevation measurements. In some embodiments, the custom third-party input includes an aerial site image, historical rainfall information, a deflection analysis, information from the Nuclear Regulatory Commission or the Post-Tensioning Institute, and drone-captured lidar point cloud data.

Aspects of this disclosure relate to a system for creating remedial geotechnical engineering plans for a structure with a recommendation design platform. In some embodiments, the system includes a processor communicatively coupled to a memory and a network interface, the network interface communicatively coupled to a network. In some embodiments, the system includes a data manager communicatively coupled to the network interface and the network. In some embodiments, the data manager is configured to receive first data from a first visit to the structure through the network, receive second data from a second visit to the structure, after the first visit, through the network, and receive third-party data for a site of the structure, through the network. In some embodiments, the system includes a model engine communicatively coupled to the data manager and an engineering interface. In some embodiments, the model engine is configured to create a model for the site and the structure based on the first data, second data, and third-party data, to approximate site soil movement, create proposed remedial geotechnical engineering plans from the model and the approximated site soil movement, and send the proposed remedial geotechnical engineering plans to the engineering interface. In some embodiments, the engineering interface is communicatively coupled to the network interface and the network and is further configured to present the proposed remedial geotechnical engineering plans to, and receive input from, a licensed geotechnical engineer to finalize the proposed remedial geotechnical engineering plans and create final remedial geotechnical engineering plans for the structure signed by the geotechnical engineer.

Particular implementations may include one or more of the following. In some embodiments, the first data is received at the data manager from a site technician. In some embodiments, the second visit to the structure is at least 1 year after the first visit. In some embodiments, the second visit to the structure is at least 5 years after the first visit. In some embodiments, the first data includes first manometer readings providing first elevation measurements for a floor of the structure, first moisture observations around a foundation of the structure, proximity of vegetation to the structure at a time of the first visit, and evidence of cracks in the structure at the time of the first visit. In some embodiments, the second data includes second manometer readings providing second elevation measurements for the floor of the structure, second moisture observations around a foundation of the structure, proximity of vegetation to the structure at a time of the second visit, and evidence of cracks in the structure at the time of the second visit. In some embodiments, the model engine is configured to construct a first topographical map of the floor of the structure using the first elevation measurements and construct a second topographical map of the floor of the structure using the second elevation measurements. In some embodiments, the third-party input includes an aerial site image, historical rainfall information, deflection analysis, information from the Nuclear Regulatory Commission or the Post-Tensioning Institute, and drone-captured lidar point cloud data.

Aspects and applications of the disclosure presented here are described below in the drawings and detailed description. Unless specifically noted, it is intended that the words and phrases in the specification and the claims be given their plain, ordinary, and accustomed meaning to those of ordinary skill in the applicable arts. The inventors are fully aware that they can be their own lexicographers if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors’ intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112(f). Thus, the use of the words “function,” “means” or “step” in the Detailed Description or Description of the Drawings or claims is not intended to somehow indicate a desire to invoke the special provisions of 35 U.S.C. § 112(f), to define the invention. To the contrary, if the provisions of 35 U.S.C. § 112(f) are sought to be invoked to define the inventions, the claims will specifically and expressly state the exact phrases “means for” or “step for” and will also recite the word “function” (i.e., will state “means for performing the function of [insert function]”), without also reciting in such phrases any structure, material or act in support of the function. Thus, even when the claims recite a “means for performing the function of ...” or “step for performing the function of ...,” if the claims also recite any structure, material or acts in support of that means or step, or that perform the recited function, then it is the clear intention of the inventors not to invoke the provisions of 35 U.S.C. § 112(f). Moreover, even if the provisions of 35 U.S.C. § 112(f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

The foregoing and other aspects, features, and advantages will be apparent from the DESCRIPTION and DRAWINGS, and from the CLAIMS if any are included.

### BRIEF DESCRIPTION OF THE DRAWINGS

Implementations will hereinafter be described in conjunction with the appended and/or included DRAWINGS.

FIG. 1A shows a flow chart for a conventional practice for identifying, selling, and performing foundation repair services.

FIG. 1B shows a flow chart for another conventional practice for identifying, selling, and performing foundation repair services.

FIG. 2 shows a flow chart for a system and method for foundation repair diagnostics and remediation design according to some embodiments.

FIG. 3 shows a schematic representation of a system for foundation repair diagnostics and remediation design according to some embodiments.

FIGS. 4A-4K show examples of potential outputs from a report or analysis of a site using a system for foundation repair diagnostics and remediation design according to some embodiments.

FIG. 5 shows a schematic diagram of a specific computing device that can be used to implement the methods and systems disclosed herein.

### DETAILED DESCRIPTION

Detailed aspects and applications of the disclosure are described below in the following drawings and detailed description of the technology. Unless specifically noted, it is intended that the words and phrases in the specification and the claims be given their plain, ordinary, and customary meaning to those of ordinary skill in the applicable arts.

In the following description, and for the purposes of explanation, numerous specific details are set forth in order to provide a thorough understanding of the various aspects of the disclosure. It will be understood, however, by those skilled in the relevant arts, that embodiments of the technology disclosed herein may be practiced without these specific details. It should be noted that there are many different and alternative configurations, devices and technologies to which the disclosed technologies may be applied. The full scope of the technology disclosed herein is not limited to the examples that are described below.

The singular forms “a,” “an,” and “the” include plural referents unless the context clearly dictates otherwise. Thus, for example, reference to “a step” includes reference to one or more of such steps. The disclosure of ranges includes the range itself and also anything subsumed therein, as well as endpoints. For example, disclosure of a range of 2.0 to 4.0 includes not only the range of 2.0 to 4.0, but also 2.1, 2.3, 3.4, 3.5, and 4.0 individually, as well as any other number subsumed in the range. Furthermore, disclosure of a range of, for example, 2.0 to 4.0 includes the subsets of, for example, 2.1 to 3.5, 2.3 to 3.4, 2.6 to 3.7, and 3.8 to 4.0, as well as any other subset subsumed in the range. As used herein “about,” “approximately,” and “substantially” mean within a percent difference of less than or equal to 20%, 10%, 5%, 3%, 2%, or 1%. Similarly, the disclosure of Markush groups includes the entire group and also any individual members and subgroups subsumed therein.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented but have been omitted for purposes of brevity.

Throughout the description and claims of this specification, the words “comprise” and “contain” and variations of the words (for example “comprising” and “comprises”) mean “including but not limited to,” and are not intended to (and do not) exclude other components.

As required, detailed embodiments of the present disclosure are included herein. It is to be understood that the disclosed embodiments are merely exemplary of the invention that may be embodied in various forms. Therefore, specific structural and functional details disclosed herein are not to be interpreted as limits, but merely as a basis for teaching one skilled in the art to employ the present invention. The specific examples below will enable the disclosure to be better understood. However, they are given merely by way of guidance and do not imply any limitation.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions.

More specifically, this disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

The foregoing and other aspects, features, and advantages will be apparent to those artisans of ordinary skill in the art from the description and figures included herein. The present disclosure relates to systems and methods for foundation repair diagnostics and remediation design.

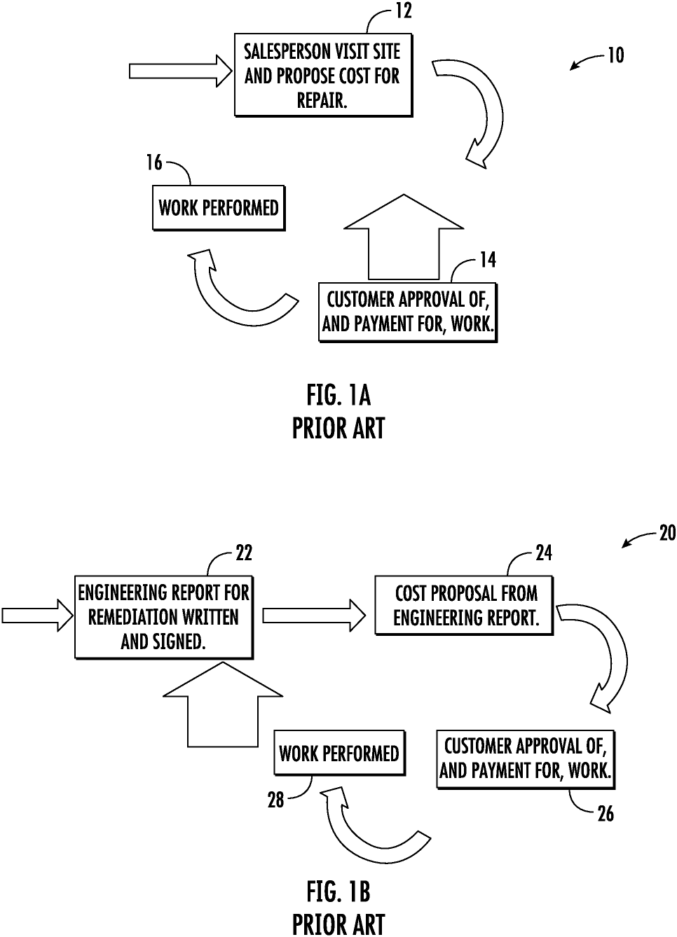

Structures (such as homes, offices, buildings, or other types of structures) typically include a foundation to give the structure strength and stability. Over time, however, as conditions of a site on which the structure is built change, foundations can become damaged or otherwise need repair. Known approaches to foundation repair have drawbacks. For example, in some instances, foundation repair services are sold by a salesperson without adequate knowledge of the repair needed (e.g., due to lack of understanding of conditions at the site), leading to repairs that lack in quality or applicability. In other instances, an engineer-driven process may result in better-quality recommendations for foundation repair services, but the cost of the process can be prohibitive. These drawbacks are explained in more detail below with respect to FIGS. 1A and 1B.

FIG. 1A shows a flow chart for a conventional practice 10 for identifying, selling, and performing foundation repair services as known in the prior art. FIG. 1A shows that a process 10 may begin at step 12 with a salesperson visiting a site that may be in need of soil remediation, such as a home, office, other building, or structure (hereinafter collectively “structure”). The contact can be initiated by the occupant or owner of the structure that has reached out for information or assistance. On the other hand, the contact may be initiated by an insurance company or the salesperson themselves. The salesperson may detect cracks or other damage to the structure, which may or may not be indicative of soil movement and a need for foundation repair. The salesperson may then recommend or sell services without fully appreciating the nature of the problem, and without an engineered solution.

In any event, if the customer (whether owner, tenant, or representative) approves the work at step 14, the work may be performed at step 16 and payment delivered, whether or not underlying issues were correctly identified and addressed.

FIG. 1B shows a flow chart for another conventional practice 20 for identifying, selling, and performing foundation repair services as known in the prior art. FIG. 1B differs from FIG. 1A in that an engineer, such as a geotechnical engineer, may be involved at step 22 in assessing the condition of the structure, and preparing an official engineering report that may be signed, sealed, or both. The report is a unique and individual piece or work product particular to the site, the engineer, and pertinent regulations. With the report and signed recommendations, a cost proposal may be created based on the engineering design at step 24. If the customer approves the cost and makes payment at step 26, the work may be performed at step 28.

Applicant has discovered that while the engineer-driven process of FIG. 1B may provide superior technical content, the cost may be greater and prohibitive in many instances. Further, Applicant has discovered that while the sales-driven approach of FIG. 1A may produce a greater number of sales and revenue for repairs, the repairs provided may lack in quality or applicability, being made by a salesperson or technician. Thus, improvements to foundation repair diagnostics and remediation design are desirable.

The present disclosure provides systems and methods for foundation repair diagnostics and remediation design that overcome the low quality/applicability of the approach in FIG. 1A and the cost-prohibitive nature of the approach in FIG. 1B. In some embodiments, the methods and systems use a recommendation/design platform that receives data from one or more site visits and information from a third party to recommend proposed remedial geotechnical engineering plans. The recommendation/design platform can then receive input from an engineer (e.g., modifications to and/or approval of the proposed remedial geotechnical engineering plans) to produce a signed engineering report and engineering recommendations in a cost-effective way. In some embodiments, an owner of the structure is given two opportunities to approve and pay for work, once for conducting the study and analysis and once for performing the remediation work. Example embodiments are discussed in further detail below.

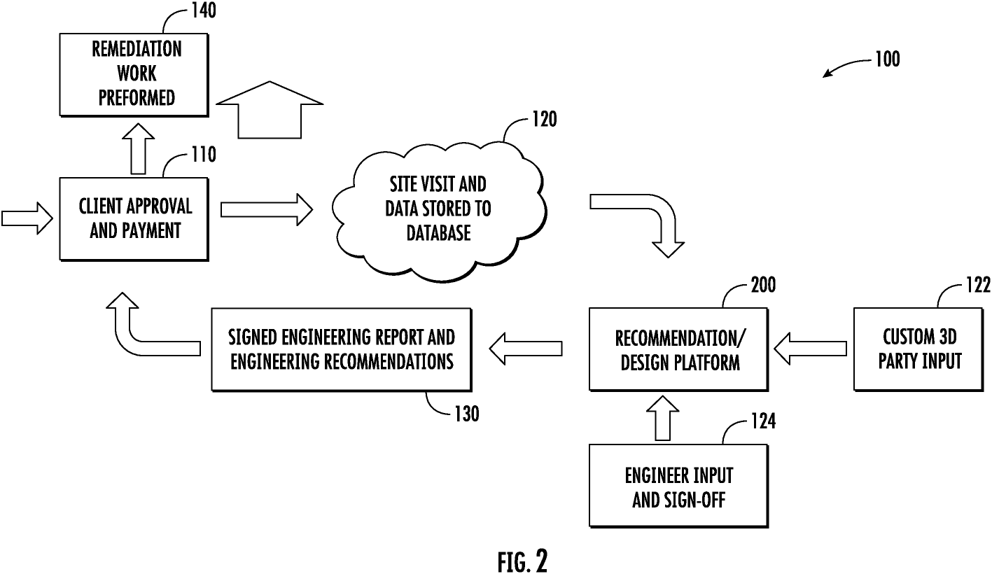

FIG. 2 shows a flow chart 100 for a new and unique approach to foundation repair diagnostics and remediation design according to some embodiments. Flow chart 100 illustrates a system and a method for foundation repair diagnostics and remediation design that comprises a recommendation/design platform 200.

As shown in FIG. 2, the improved process and system for delivery of foundation repair diagnostics and remediation design services may begin at operation 110, with client or customer approval and payment for services. In some embodiments, the approval of services may first be approval to conduct a study and produce an engineering report as indicated by the arrows coming from left to right at operation 110. In some embodiments, operation 110 may also include a second approval (at a later stage of the process) for remediation work being performed, as indicated by the arrows coming from bottom to top at operation 110.

In some embodiments, at operation 120, after the first client approval, one or more site visits may be made to inspect and measure the structure, damage to the structure, and soil and related conditions. The acquired data may be stored in a database for subsequent retrieval, use, and analysis. An engineering recommendation may then be prepared using a customized platform 200, described in greater detail below, that includes (i) inputs from the database (based on operation 120), (ii) custom third-party inputs (at operation 122), and (iii) engineer input and sign-off (at operation 124).

As noted above, operation 120 may represent multiple site visits. For example, in some embodiments, a method for creating remedial geotechnical engineering plans for a structure with a recommendation design platform 200 may include receiving first data at the recommendation design platform 200 from a first visit by a site technician to the structure and receiving second data at the recommendation design platform 200 from a second visit to the structure after the first visit. The first data may include inputs from the database, such as site-specific measures from a single period of a day, week, or month from an earlier site visit, and may also include multiple visits spanning a period of time between multiple visits, such as any number of months or years. Multiple visits spanning a period of time may show changes in soil and structure damage or movement over time, wherein measuring movement of soil over a period of 1 year, or of 5 years may be beneficial to track movement. In some embodiments, the second visit is at least five years after the first visit. In some embodiments, the second visit is at least one year after the first visit. The site visits may be made by a site technician (or site tech), rather than a salesperson, thereby bringing additional technical expertise and training to the site inspection. Signs of stress, floor system stress, floor survey results, manometer data points, observations including photos of damage, first elevation measurements for a floor of the structure, second elevation measurements for a floor of the structure, moisture observations around a foundation of the structure, proximity of vegetation to the structure, evidence of cracks in the structure, and foundation observations and analysis may all be part of the first data, the second data, or both.

The method may further comprise receiving custom third-party input at the recommendation design platform 200 as shown at operation 122. Custom third-party inputs may include data from any number of desired sources, including up to 17 sources (or more) that are optimized and taken together to provide unique, beneficial, and unexpected results relating to the generation of specific, unique, and economical site-specific recommendations for a particular site, structure, or both. Third-party input may comprise an aerial site image, historical rainfall information, a deflection analysis, information from the U.S. Nuclear Regulatory Commission (“NRC”) or the Post-Tensioning Institute (“PTI”), and drone captured lidar point cloud data. As noted above, custom third-party inputs may include data from any number of desired sources, including up to 17 sources (or more). Sources or data inputs may include: 3DField, RU topo, deflection analysis (which may include information or data from the NCR website, the PTI, or both), Lidar point cloud (e.g., from a drone), satellite view of site, topographical map and a 3D topographical map, and precipitation for site of the structure area. Precipitation for the site of the structure area can inform analysis re: soil moisture conditions and likely changes from pre-construction to post construction of the structure, and how expansive soils may be affected. For example, in a dry climate like in Phoenix AZ, the dry soils may become wetter through irrigation, plumbing leaks, or other causes such that previously dry unsaturated expansive soils become more saturated and expand, causing heave under, and to, the structure. On the other hand, in a wetter climate like in Houston TX, the wet soils may become dryer after a structure is placed over soil and prevents precipitation from traveling to the soil below the structure such that saturated expansive soils become drier, decrease in volume, and cause settling under, and to, the structure.

The method may further comprise comparing, by the recommendation design platform 200, the first elevation measurements for the floor of the structure and the second elevation measurements for the floor of the structure to determine soil movement over time. In some embodiments, manometer readings at the time of the first visit provide the first elevation measurements and manometer readings at the time of the second visit provide the second elevation measurements.

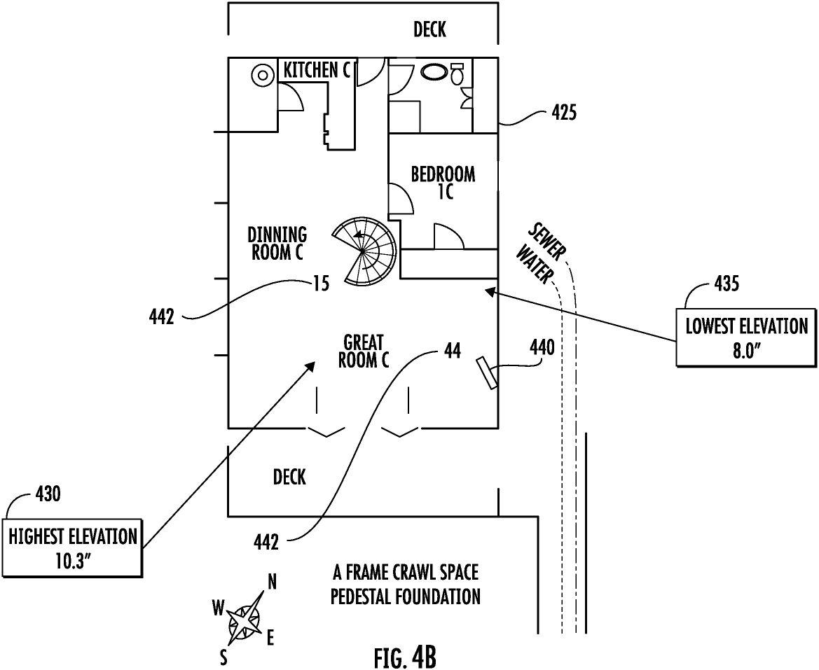

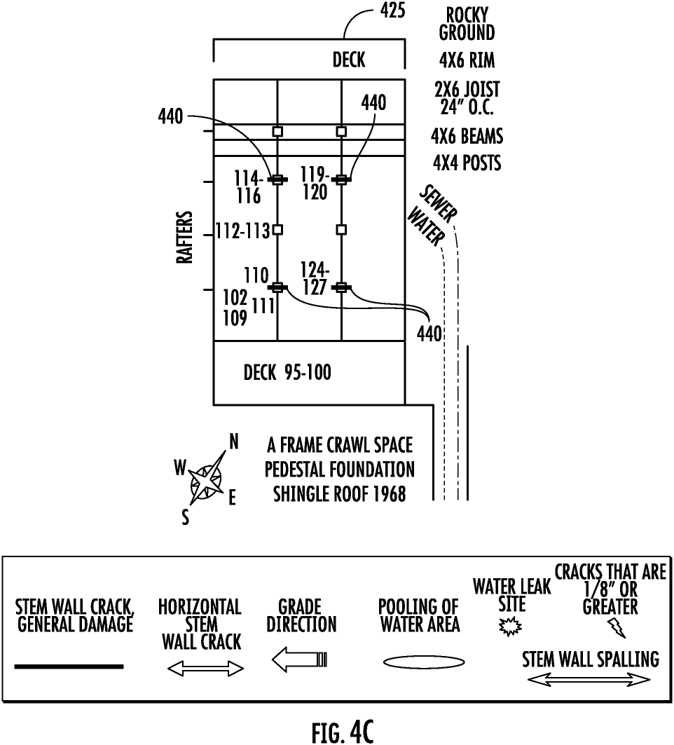

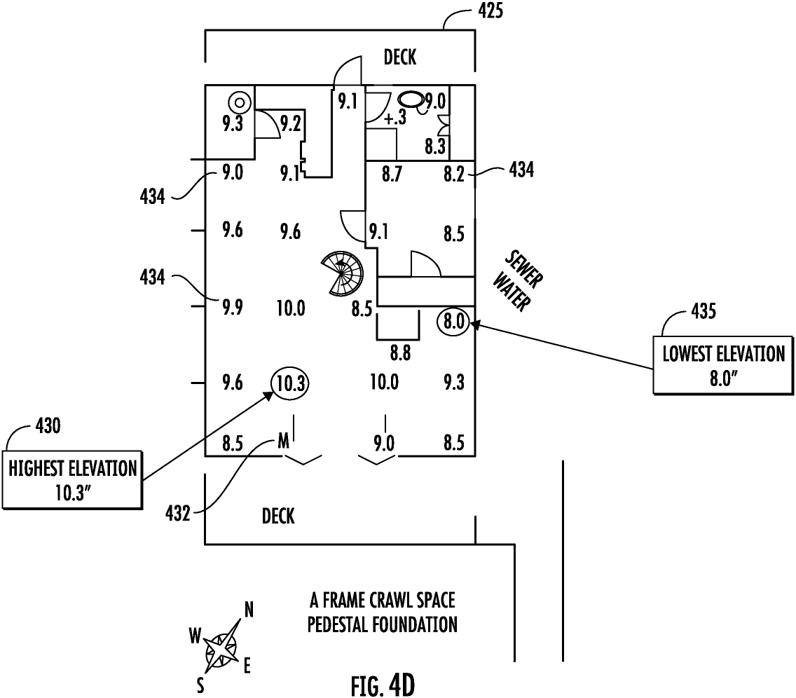

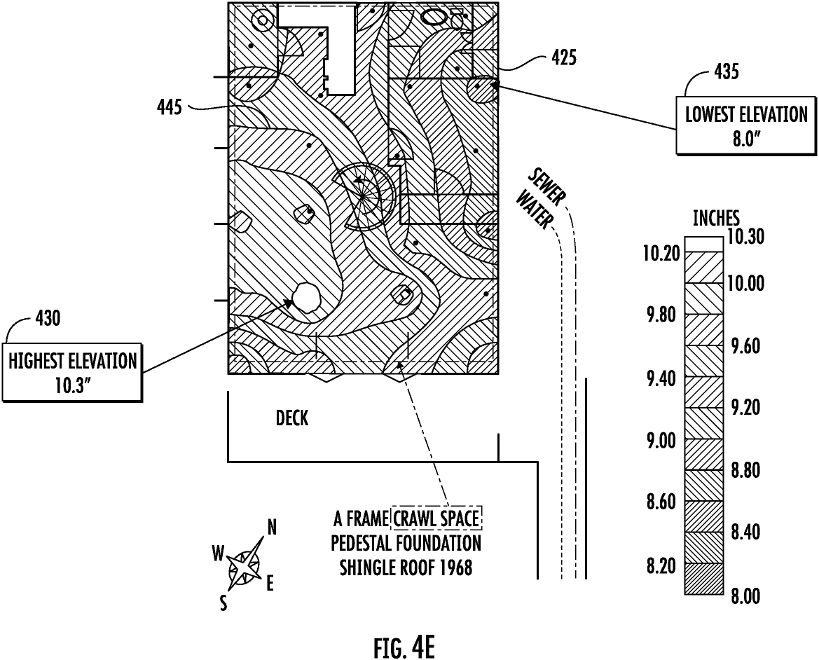

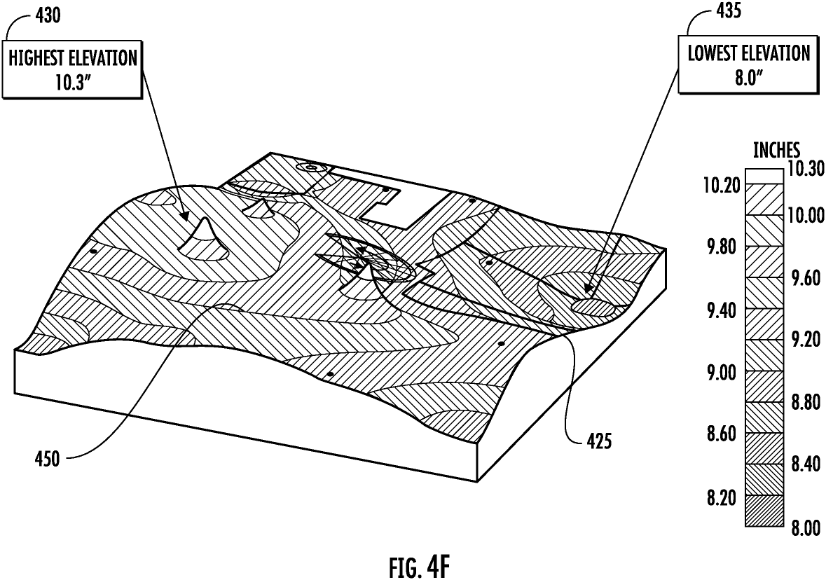

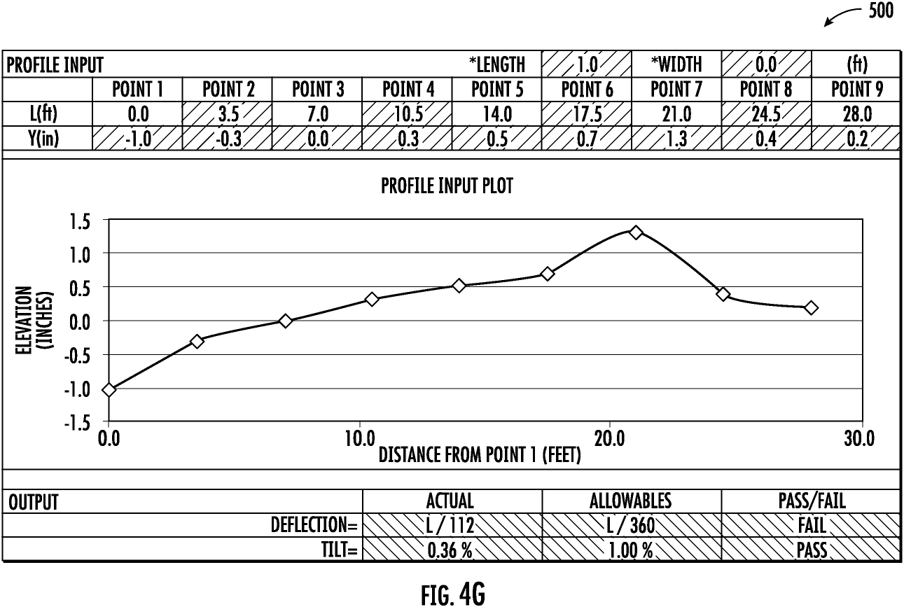

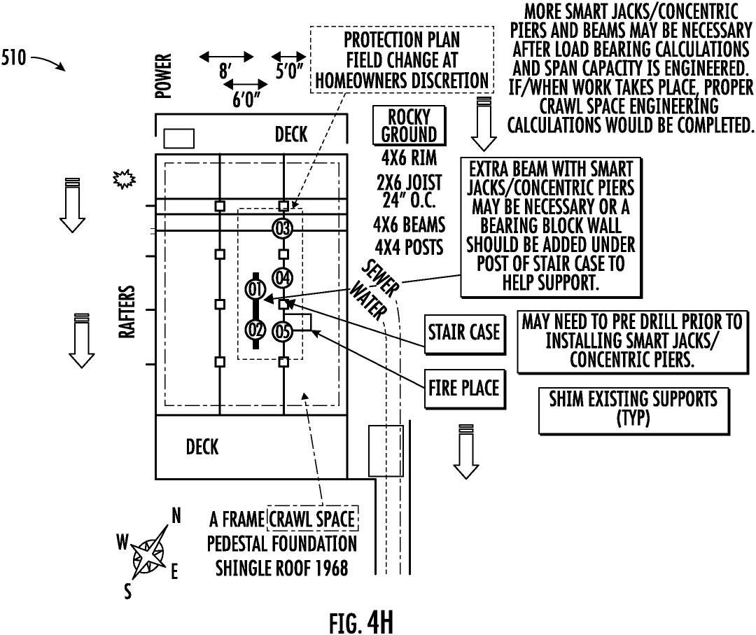

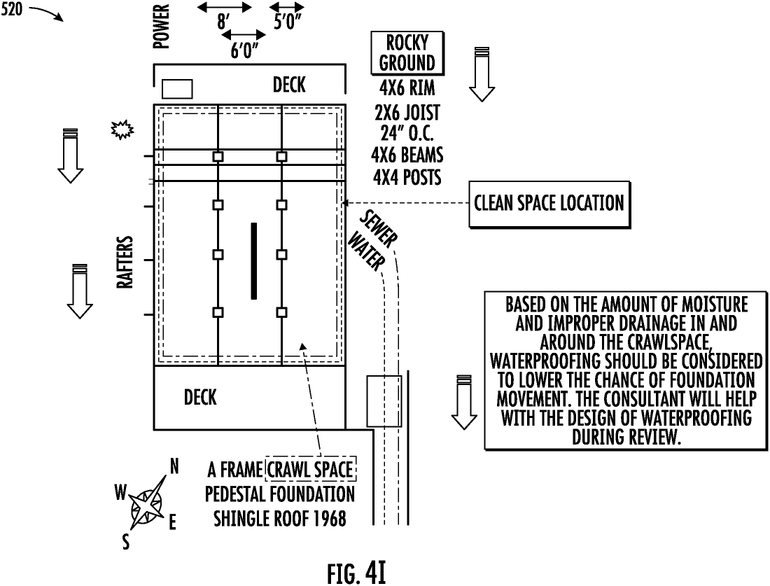

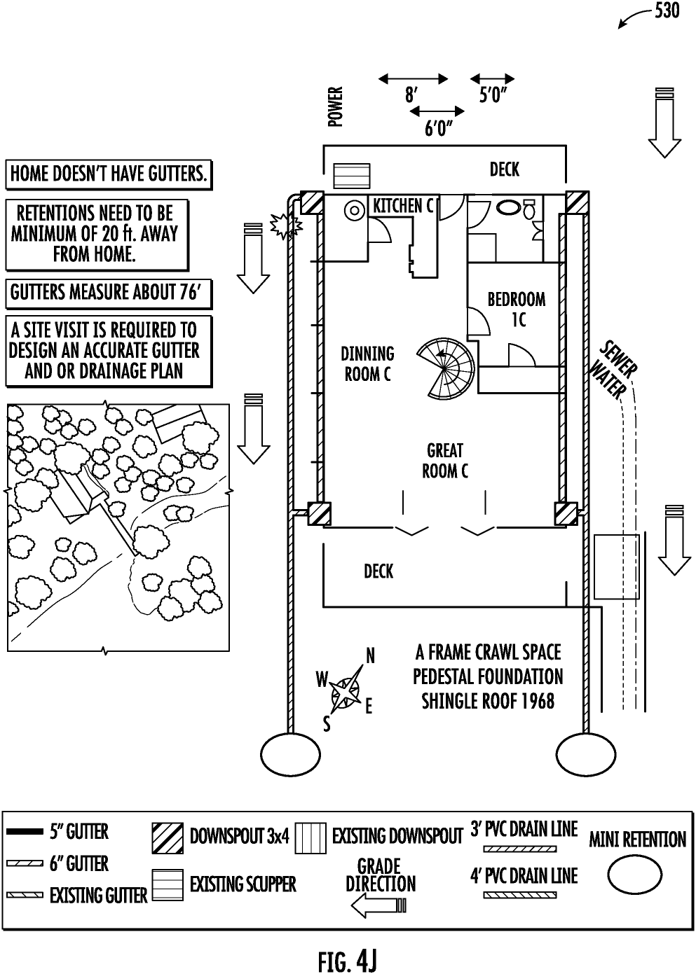

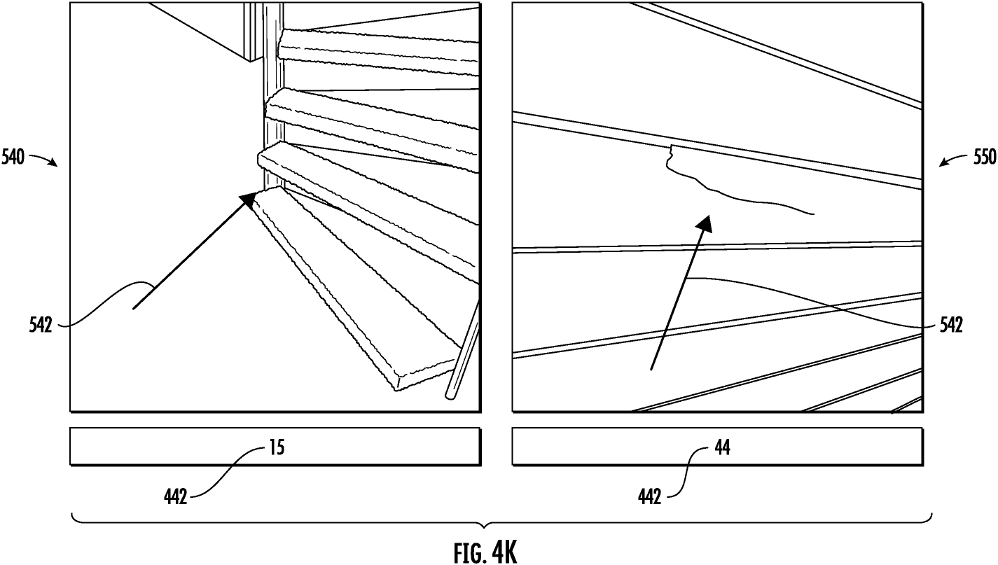

In some embodiments, topographical maps of the floor of the structure may be constructed by the recommendation design platform 200 using the elevation measurements (see FIGS. 4E-4F). For example, a first topographical map of the floor of the structure may be constructed using the first elevation measurements and a second topographical map of the floor of the structure using the second elevation measurements. In some embodiments, the first topographical map comprises a two-dimensional topographical map (see FIG. 4E). In some embodiments, the first topographical map comprises a three-dimensional topographical map (see FIG. 4F). In some embodiments, both a two-dimensional topographical map and a three-dimensional topographical map are constructed using the first elevation measurements. A floor plan of the structure may be overlaid on the topographical maps of the floor of the structure disclosed herein (see FIGS. 4E and 4F). In some embodiments, a heatmap may be included over the topographical maps to visually highlight the elevation measurements (as done in FIGS. 4E and 4F).

In some embodiments, the recommendation design platform 200 may construct an additional heatmap of the floor of the structure based on the determined soil movement over time. The additional heatmap visually highlights areas of the floor of the structure where the greatest soil movement is occurring. Thus, a user (e.g., an engineer) would be able to see both the static differences in elevation at various locations of the structure and how quickly elevation is changing at various locations of the structure.

The method may further comprise creating, by the recommendation design platform 200, proposed remedial geotechnical engineering plans for the structure from the determined soil movement over time, evidence of cracks in the structure, and moisture observations around a foundation of the structure.

The method may further comprise receiving, at the recommendation design platform 200, modifications to the proposed remedial geotechnical engineering plans from a licensed engineer, as shown at operation 124 in FIG. 2. The recommendation design platform 200 may also receive a sign-off from the licensed engineer at operation 124, after which the recommendation design platform 200 outputs sealed remedial geotechnical engineering plans for the structure at operation 130. Thus, the recommendation design platform 200 may provide unique, specific, and technical recommendations that may be reviewed, adjusted, modified, and approved by the engineer to produce a signed/sealed set of drawings or plans at a competitive economic price point for improving or remediating the site or structure under consideration or review. The engineering plans may include: repair recommendations, additional recommendations, a protection plan, a clean space plan, and a drainage plan. In some embodiments, recommendation design platform 200 may include a search feature that allows users (e.g., an engineer) to query information and receive information based on data from the site visits, third-party input, or other public information that provides relevant detail to the user.

As noted above, after the signed engineering report and engineering recommendations/plans are outputted at operation 130, the client again has the opportunity to decide whether to approve and pay for the work involved with those plans (shown at operation 110). After client approval and payment, the remediation work is performed at operation 140.

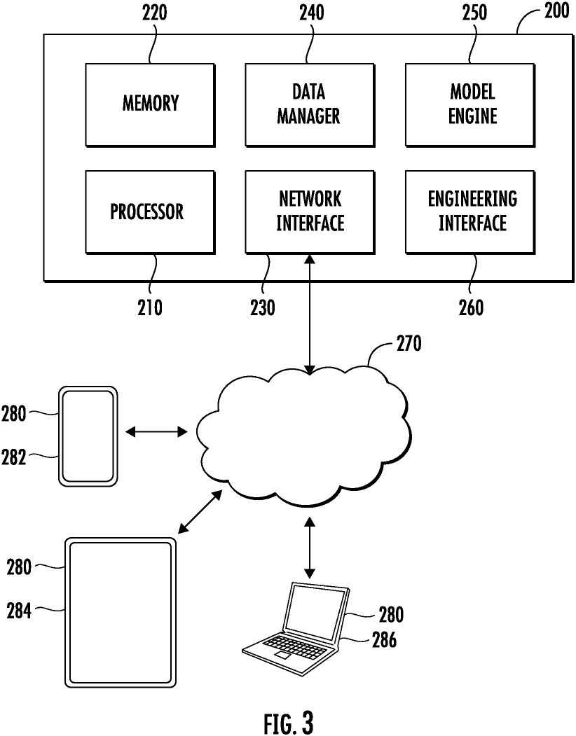

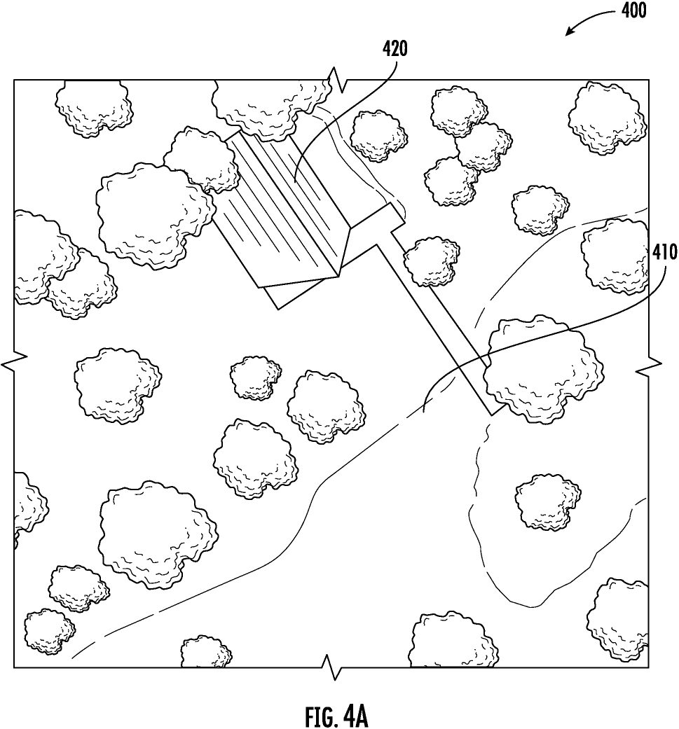

A system for foundation repair diagnostics and remediation design (for creating remedial geotechnical engineering plans) is shown, for example, in FIG. 3. The system may include recommendation design platform 200, a network 270, and a plurality of electronic devices 280. The recommendation design platform 200 and the plurality of electronic devices 280 may communicate over network 270. Electronic devices 280 may be a smartphone 282, a tablet 284, a computer 286, or any other type of electronic device. Users (e.g., a site technician, an engineer, a third party, etc.) may use electronic devices 280 to provide the input discussed in this application to recommendation design platform 200. Network 270 may be a local area network or a wide area network (e.g., the internet).

In some embodiments, the recommendation design platform 200 may comprise a processor 210, a memory 220, a network interface 230, a data manager 240, a model engine 250, and an engineering interface 260. In some embodiments, processor 210 is communicatively coupled to memory 220 and network interface 230. The network interface 210 may be communicatively coupled to network 270.

In some embodiments, data manager 240 may be communicatively coupled to the network interface 230 and the network 270. Data manager 240 is configured to receive first data from a first visit to the structure through the network, receive second data from a second visit to the structure (after the first visit) through the network, and receive third-party data for the site, through the network. In some embodiments, data manager 240 comprises the database referenced in operation 120 of FIG. 2. In some embodiments, the database may be maintained separately (e.g., at a distinct server) and is communicatively coupled to network 270 so that the data can subsequently be provided to data manager 240.

In some embodiments, model engine 250 may be communicatively coupled to the data manager 240 and engineering interface 260. In some embodiments, the model engine 250 is configured to create a model for the site and structure (see FIGS. 4A-4K). The model for the site and structure may be based on the first data, second data, and third-party data. In some embodiments, model engine 250 is configured to construct first and second topographical maps of the floor of the structure using the first and second elevation measurements, respectively. The model engine 250 is also configured to approximate site soil movement. For example, model engine 250 may compare the first and second elevation measurements and create a heatmap of the floor of the structure, which may show locations that experienced the greatest difference in elevation measurements between the first and the second visit. The model engine 250 is also configured to create proposed remedial geotechnical engineering plans from the model of the site and the approximated site soil movement. In some embodiments, the model engine 250 is configured to send the proposed remedial geotechnical engineering plans to the engineering interface 260. In some embodiments, an engineer may interact with the proposed plans at the engineering interface 260 (as discussed for operation 124 in FIG. 2) via an electronic device 280 over network 270. In some embodiments, recommendation design platform may be part of an electronic device 280.

By utilizing the system and method described herein, an engineer need not prepare an entire report alone, or with conventional tools, such as writing a report in publisher, and needing to go back and forth among different applications to reference and incorporate data for the report. Within the system, the model engine 250 may propose customized or default language for a preparer to choose from, including suggestions made by artificial intelligence (AI), and suggested language based on algorithms accounting for known inputs and variables. Changes to proposed remedial geotechnical engineering plans may be adjusted by making selections from a drop-down menu with recommendations, and suggested sections for where the material may be placed in a report. In some embodiments, recommendation design platform 200 may use built-in artificial intelligence using natural language processing to generate text for the report/engineering recommendation based on the data inputted into recommendation design platform 200. Pictures taken on site may be tied to a location on the floor-plan, and included in the proposed remedial geotechnical engineering plans or report.

Cost estimates for what a client would pay to implement the proposed remedial geotechnical engineering plans may also be generated. With improved and streamlined identification of geotechnical problems and good cost-efficient remediation plans for the same, structure owners, such as home owners, may be better situated to take advantage of insurance, such as home owner’s insurance to effectuate change and prevent longer term damage and expense. As a whole, the industry may become more transparent, and no or little cost would need to be incurred for providing the proposed remedial geotechnical engineering plans, but instead, those costs could be reduced or minimized and the dollars spent would be for the remedial work done. Furthermore, with many parties contributing data to the data manager, additional geotechnical insights will be available for sites with a single data set, where similar, adjacent, or geographically similar sites may benefit from related data in identifying and diagnosing soil movement issues.

FIGS. 4A-4K show examples of potential outputs from a report or analysis output for a first unique site. FIG. 4A shows an ariel view 400 for a first structure 420 at a first site 410.

FIG. 4B shows a plan view of a floor plan 425 for an A-frame structure with a pedestal foundation with a crawl space. High point 430 and low point 440 of the floor are also shown relative to manometer readings with a baseline or initial measure of 9 inches. Signs of stress are indicated generally, with a particular instance of a wall crack (indicated by marker 440) shown near the lower right corner in the plan view of the structure. Thus, markers 440 may be displayed on the floor plan 425 to indicate locations of the evidence of the cracks in the structure at the time of the first visit (or second visit). In some embodiments, one or more identifiers 442 may be included on floor plan 425 to identify locations of interest, such as locations of damage.

FIG. 4C shows additional detail of floor system stress, and particularly of stem wall cracking or general damage.

FIG. 4D shows the manometer reading results 434 with the location of the manometer 432 shown with an M and positioned at a setting or position of 9 inches, and the other readings also shown in inches.

FIG. 4E shows a topographical map 445 constructed from the manometer reading results 434 showing the relative elevations of the structure floor.

FIG. 4F shows a 3D topographical map 450 constructed from the manometer reading results 434 showing the relative elevations of the structure floor, similar to what was shown in 2D in FIG. 4E.

Observations reported on the first site further include synthesis of observations and interpretation and conclusions that may be facilitated by machine learning or artificial intelligence (collectively hereinafter “AI”), as well as algorithms on the platform. AI on or within the platform may provide recommendations based on information, reports, or other data stored in the database, as well as third-party inputs, wherein the third-party inputs further include user input, and may include such items as data or information on well drilling, precipitation, custom or individualized user inputs. Additional or custom user input may also be incorporated or considered by the platform and platform AI in a probative rather than dispositive way to influence or direct results and recommendations produced. Further, additional or custom user input, being optional, may not be used and would not be required. As such, user input may or may not be outcome determinative.

For example, for Site 1 the structure could be experiencing minor foundation settlement at the northeast portion of the structure as shown by the lower readings shown on the topographical map 445 of FIG. 4E. The drop off in floor elevations on the topographical map is consistent with a foundation settlement pattern. Settlement can be caused by one or any combination of many factors including sub-grade saturation of moisture due to poor drainage, years of storm runoff, plumbing leaks, improper compaction, the lack of a proper foundation system, and/or (in most cases) natural earth movement. Site observation included excessive moisture in the crawlspace. An encapsulation system/moisture barrier should be installed to help address the moisture issue within the crawlspace.

The Foundation Performance Association (FPA) “Guidelines for the Evaluation of Foundation Movement for Residential And Other Low-Rise Buildings” were adopted to correlate acceptable and unacceptable distress phenomena with actual survey elevations. Deflection and Tilt calculations were performed and compared to allowable values. For this engineered analysis, the deflection of the slab (L/112) was more than the allowable deflection limit of L/360. In addition, the tilt of the slab (0.36%) was less than the allowable tilt of 1.00%. While the deflection of the slab was more than the allowable limit, the overall damage is minor in nature. Analysis and results 500 of the deflection limit and tilt are shown in FIG. 4G and discussed below. The analysis discussed below with respect to FIG. 4G may be included as part of an output from a report or analysis output. The system may provide instructions to compute a deflection limit, tilt, and k-factored deflection limit. The instructions may include instructions to input distance along the profile into the cross-hatched “L” cells (shown in FIG. 4G under the profile input section) from one edge of the slab to the other. The instructions may indicate that spacing may be unequal, but the first L must be zero, and each successive L is greater than the previous one. The instructions may also include instructions to input elevations measured at each L into the cross-hatched “Y” cells (shown in FIG. 4G under the profile input section). The instructions may indicate to start with Point 1 and, for instances with less than 9 data sets, to leave extra cells empty (rather than entering zero). The instructions may further indicate that if a non-principal axis is used, enter Length and Width, but otherwise let Length equal 1 and Width equal 0.01 (see top right section of FIG. 4G). The instructions may further indicate that L/360 (the maximum allowable deflection limit) is used when L is along a principal axis, but if length L is not parallel to a principal axis, L is modified by the k-factor to adjust the maximum allowable deflection limit to as much as L/255 for k-factors up to 1.414.

In some embodiments, user input is in the cross-hatched cells in the profile input section only and shown in the input plot. The output is in the cross-hatched cells shown in the output section. The deflection between points 1 and 3 may be determined as follows: Deflection = Y2-[Y1+(L 12/L)(Y3-Y1)], where Points 1 and 3 are end points of any intermediate span chosen by the spreadsheet, and Point 2 is any point chosen by the spreadsheet that falls in between Points 1 and 3. The edge-to-edge tilt may be determined as follows: Tilt = (100%) [Yb-Ya]/Lab. The k-factor may be determined as follows: k = SQRT(Length^2 + Width^2)/Length. Additional information on the analysis and spreadsheet (in FIG. 4G) may be provided by the FPA.

Repair recommendations for the first site, based on the above research and analysis, include a protection plan designed to stop the area from any additional settlement and further damages. Support in the areas of the stairs and fireplace to stabilize the support beams in the crawl space may be accomplished with SmartJacks. SmartJacks are adjustable galvanized supports engineered to be placed under the sagging floors to help prevent settlement of the floor joist system. The SmartJack sequence should start at approximately 2′ off each perimeter wall and should not be spaced more than 7′ on center (exact spacing to be determined after load bearing calculations). An engineered push pier will be driven concentrically beneath the beam at each Smart Jack location to provide a footing for each Smart Jack. If the installation of concentric piers is not possible, a concrete footing of engineered size will be poured beneath the smart jack to distribute the load. The SmartJacks will then be cut to size and set in place. Finally, the units will be adjusted to lift the sagging floors back to their best functioning point or the Highest Practical Maximum.

Repair recommendations for the first site may further include ameliorating excessive dampness in the crawlspace below the floor of the structure. The source of the water is unknown, but may be from snow melt. The moisture has begun to negatively impact wood/timber supports. A new encapsulation system should be properly installed. Pipes should be installed and connected to a fan system to create suction to help remove excess moisture. Drainage matting should be laid on top of the crawl space floor to increase flow to the pipes and to help prevent moisture from getting trapped under the encapsulation materials. The new system should include a tear resistant thick material that is mechanically fastened to the perimeter walls and wraps the crawl space supports to help prevent moisture from wicking up through the soil into the crawl space. This will help prevent mold, rot, and odors from entering the crawl space and the structure. Further, since storm runoff is responsible for the majority of the moisture that pools next to the foundation, gutters need to be installed to prevent the storm runoff from increasing the amount of foundation movement. A proper gutter system should be installed to discharge the storm runoff a minimum of 10 feet, preferably 20 feet away from the foundation. It is not recommended to install gutters that discharge next to the foundation as this will only increase the probability of a foundation problem.

Moisture management around the structure may also advantageously comprise the following: (i) hire a reputable plumbing leak detector and repair service to check both pressure and sewer lines; (ii) ensure the grading of the terrain is sloped downwards at 5% slope away from the structure at all areas of the perimeter; and (iii) stop irrigating plants that are near the foundation and make sure there is nothing trapping the moisture from flowing away from the structure. When permanently stabilizing, lifting and/or mitigating a foundation movement problem, it is recommended to wait at least 6 months before investing in cosmetic repairs.

FIG. 4H shows a proposed protection plan 510 for the first site 410 based on the observations and analysis. FIG. 4I shows a clean space plan 520 for the first structure 420 based on the foregoing. FIG. 4J shows a proposed drainage plan 530 based on the foregoing. FIG. 4K shows photographs 540 and 550 documenting exemplary damage within the structure, which may be highlighted by an indicator 542, pointing out the damage. In some embodiments, the identifier 442 of the damage locations from the floor plan 425 (see FIG. 4B) may be included with the photographs 540 and 550 for reference.

The examples of potential outputs from a report or analysis output for a first unique site shown in FIGS. 4A-4K may be based on one visit by a site technician, or they may be based on multiple visits. For example, the topographical map 445 shown in FIG. 4E (and/or the topographical map 450 shown in FIG. 4F) may be constructed using first elevation measurements from a first visit. A second topographical map of the floor of the structure 420 may be constructed using second elevation measurements from a second visit. Such a topographical map would be similar to the ones shown in FIGS. 4E and 4F, but with different measurement values. In some embodiments, a heatmap may be included over the topographical map to visually highlight the elevation measurements (as done in FIGS. 4E and 4F). In some embodiments, an additional heatmap of the floor of the structure 420 may be constructed based on determined soil movement over time (which may be determined by comparing the first and second elevation measurements), as discussed above.

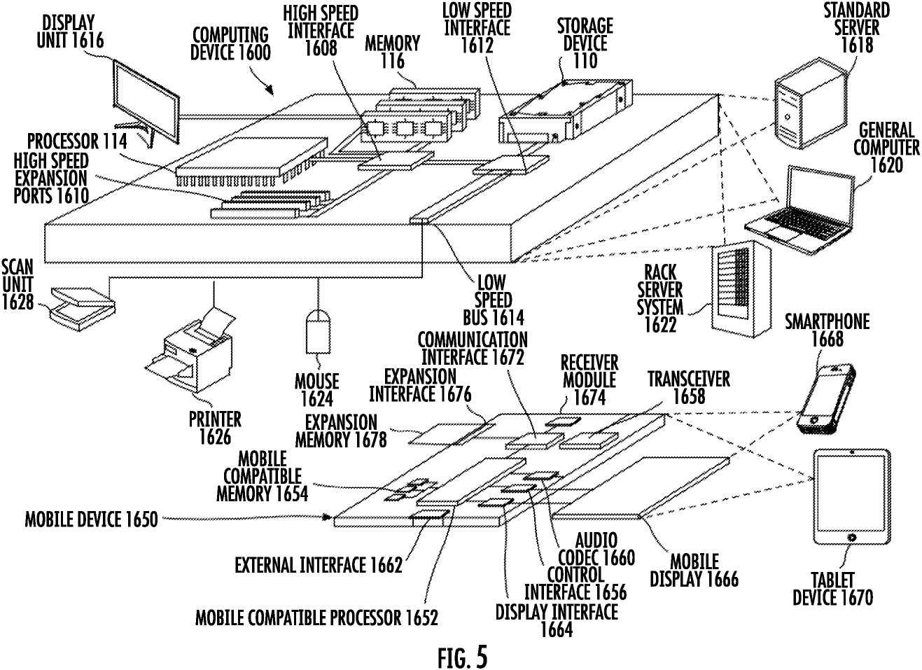

FIG. 5 is a schematic diagram of specific computing device 1600 and a specific mobile computing device 1630 that can be used to perform and/or implement any of the embodiments disclosed herein. In one or more embodiments, the user electronic device on which the app is run, as well as the marketplace server, may be the specific computing device 1600 or mobile device 1650, according to various embodiments.

The specific computing device 1600 may represent various forms of digital computers, such as laptops, desktops, workstations, personal digital assistants, servers, blade servers, mainframes, and/or other appropriate computers. The specific mobile computing device 1630 may represent various forms of mobile devices, such as smartphones, camera phones, personal digital assistants, cellular telephones, and other similar mobile devices. The components shown here, their connections, couples, and relationships, and their functions, are meant to be exemplary only, and are not meant to limit the embodiments described and/or claimed, according to an embodiment.

The specific computing device 1600 may include a processor 114, a memory 116, a storage device 1606, a high-speed interface 1608 coupled to the memory 116 and a plurality of high-speed expansion ports 1610, and a low-speed interface 1612 coupled to a low-speed bus 1614 and a storage device 1606. In an embodiment, each of the components heretofore may be inter-coupled using various buses, and may be mounted on a common motherboard and/or in other manners as appropriate. The processor 114 may process instructions for execution in the specific computing device 1600, including instructions stored in the memory 116 and/or on the storage device 1606 to display a graphical information for a GUI on an external input/output device, such as a display unit 1616 coupled to the high-speed interface 1608, according to an embodiment.

In other embodiments, multiple processors and/or multiple buses may be used, as appropriate, along with multiple memories and/or types of memory. Also, a plurality of specific computing device 1600 may be coupled with, with each device providing portions of the necessary operations (e.g., as a server bank, a group of blade servers, and/or a multi-processor system).

The memory 116 may be coupled to the specific computing device 1600. In an embodiment, the memory 116 may be a volatile memory. In another embodiment, the memory 116 may be a non-volatile memory. The memory 116 may also be another form of computer-readable medium, such as a magnetic and/or an optical disk. The storage device 1606 may be capable of providing mass storage for the specific computing device 1600. In an embodiment, the storage device 1606 may be includes a floppy disk device, a hard disk device, an optical disk device, a tape device, a flash memory and/or other similar solid state memory device. In another embodiment, the storage device 1606 may be an array of the devices in a computer-readable medium previously mentioned heretofore, computer-readable medium, such as, and/or an array of devices, including devices in a storage area network and/or other configurations.

A computer program may be comprised of instructions that, when executed, perform one or more methods, such as those described above. The instructions may be stored in the memory 116, the storage device 1606, a memory coupled to the processor 114, and/or a propagated signal.

The high-speed interface 1608 may manage bandwidth-intensive operations for the specific computing device 1600, while the low-speed interface 1612 may manage lower bandwidth-intensive operations. Such allocation of functions is exemplary only. In an embodiment, the high-speed interface 1608 may be coupled to the memory 116, the display unit 1616 (e.g., through a graphics processor and/or an accelerator), and to the plurality of high-speed expansion ports 1610, which may accept various expansion cards.

In an embodiment, the low-speed interface 1612 may be coupled to the storage device 1606 and the low-speed bus 1614. The low-speed bus 1614 may be comprised of a wired and/or wireless communication port (e.g., a Universal Serial Bus (“USB”), a Bluetooth® port, an Ethernet port, and/or a wireless Ethernet port). The low-speed bus 1614 may also be coupled to the scan unit 1628, a printer 1626, a keyboard, a mouse 1624, and a networking device (e.g., a switch and/or a router) through a network adapter.

The specific computing device 1600 may be implemented in a number of different forms, as shown in the figure. In an embodiment, the specific computing device 1600 may be implemented as a standard server 1618 and/or a group of such servers. In another embodiment, the specific computing device 1600 may be implemented as part of a rack server system 1622. In yet another embodiment, the specific computing device 1600 may be implemented as a general computer 1620 such as a laptop or desktop computer. Alternatively, a component from the specific computing device 1600 may be combined with another component in a specific mobile computing device 1630. In one or more embodiments, an entire system may be made up of a plurality of specific computing device 1600 and/or a plurality of specific computing device 1600 coupled to a plurality of specific mobile computing device 1630.

In an embodiment, the specific mobile computing device 1630 may include a mobile compatible processor 1632, a mobile compatible memory 1634, and an input/output device such as a mobile display 1646, a communication interface 1652, and a transceiver 1638, among other components. The specific mobile computing device 1630 may also be provided with a storage device, such as a microdrive or other device, to provide additional storage. In an embodiment, the components indicated heretofore are inter-coupled using various buses, and several of the components may be mounted on a common motherboard.

The mobile compatible processor 1632 may execute instructions in the specific mobile computing device 1630, including instructions stored in the mobile compatible memory 1634. The mobile compatible processor 1632 may be implemented as a chipset of chips that include separate and multiple analog and digital processors. The mobile compatible processor 1632 may provide, for example, for coordination of the other components of the specific mobile computing device 1630, such as control of user interfaces, applications run by the specific mobile computing device 1630, and wireless communication by the specific mobile computing device 1630.

The mobile compatible processor 1632 may communicate with a user through the control interface 1636 and the display interface 1644 coupled to a mobile display 1646. In an embodiment, the mobile display 1646 may be a Thin-Film-Transistor Liquid Crystal Display (“TFT LCD”), an Organic Light Emitting Diode (“OLED”) display, and another appropriate display technology. The display interface 1644 may comprise appropriate circuitry for driving the mobile display 1646 to present graphical and other information to a user. The control interface 1636 may receive commands from a user and convert them for submission to the mobile compatible processor 1632.

In addition, an external interface 1642 may be provide in communication with the mobile compatible processor 1632, so as to enable near area communication of the specific mobile computing device 1630 with other devices. External interface 1642 may provide, for example, for wired communication in some embodiments, or for wireless communication in other embodiments, and multiple interfaces may also be used.

The mobile compatible memory 1634 may be coupled to the specific mobile computing device 1630. The mobile compatible memory 1634 may be implemented as a volatile memory and a non-volatile memory. The expansion memory 1658 may also be coupled to the specific mobile computing device 1630 through the expansion interface 1656, which may comprise, for example, a Single In Line Memory Module (“SIMM”) card interface. The expansion memory 1658 may provide extra storage space for the specific mobile computing device 1630, or may also store an application or other information for the specific mobile computing device 1630.

Specifically, the expansion memory 1658 may comprise instructions to carry out the processes described above. The expansion memory 1658 may also comprise secure information. For example, the expansion memory 1658 may be provided as a security module for the specific mobile computing device 1630, and may be programmed with instructions that permit secure use of the specific mobile computing device 1630. In addition, a secure application may be provided on the SIMM card, along with additional information, such as placing identifying information on the SIMM card in a non-hackable manner.

The mobile compatible memory may include a volatile memory (e.g., a flash memory) and a non-volatile memory (e.g., a non-volatile random-access memory (“NVRAM”)). In an embodiment, a computer program comprises a set of instructions that, when executed, perform one or more methods. The set of instructions may be stored on the mobile compatible memory 1634, the expansion memory 1658, a memory coupled to the mobile compatible processor 1632, and a propagated signal that may be received, for example, over the transceiver 1638 and/or the external interface 1642.

The specific mobile computing device 1630 may communicate wirelessly through the communication interface 1652, which may be comprised of a digital signal processing circuitry. The communication interface 1652 may provide for communications using various modes and/or protocols, such as, a Global System for Mobile Communications (“GSM”) protocol, a Short Message Service (“SMS”) protocol, an Enhanced Messaging System (“EMS”) protocol, a Multimedia Messaging Service (“MMS”) protocol, a Code Division Multiple Access (“CDMA”) protocol, Time Division Multiple Access (“TDMA”) protocol, a Personal Digital Cellular (“PDC”) protocol, a Wideband Code Division Multiple Access (“WCDMA”) protocol, a CDMA2000 protocol, and a General Packet Radio Service (“GPRS”) protocol.

Such communication may occur, for example, through the transceiver 1638 (e.g., radio-frequency transceiver). In addition, short-range communication may occur, such as using a Bluetooth®, Wi-Fi, and/or other such transceiver. In addition, a GPS (“Global Positioning System”) receiver module 1654 may provide additional navigation-related and location-related wireless data to the specific mobile computing device 1630, which may be used as appropriate by a software application running on the specific mobile computing device 1630.

The specific mobile computing device 1630 may also communicate audibly using an audio codec 1640, which may receive spoken information from a user and convert it to usable digital information. The audio codec 1640 may likewise generate audible sound for a user, such as through a speaker (e.g., in a handset smartphone of the specific mobile computing device 1630). Such a sound may comprise a sound from a voice telephone call, a recorded sound (e.g., a voice message, a music files, etc.) and may also include a sound generated by an application operating on the specific mobile computing device 1630.

The specific mobile computing device 1630 may be implemented in a number of different forms, as shown in the figure. In an embodiment, the specific mobile computing device 1630 may be implemented as a smartphone 1648. In another embodiment, the specific mobile computing device 1630 may be implemented as a personal digital assistant (“PDA”). In yet another embodiment, the specific mobile computing device, 1630 may be implemented as a tablet device 1650.

Various embodiments of the systems and techniques described here can be realized in a digital electronic circuitry, an integrated circuitry, a specially designed application specific integrated circuits (“ASICs”), a piece of computer hardware, a firmware, a software application, and a combination thereof. These various embodiments can include embodiment in one or more computer programs that are executable and/or interpretable on a programmable system including one programmable processor, which may be special or general purpose, coupled to receive data and instructions from, and to transmit data and instructions to, a storage system, one input device, and at least one output device.

These computer programs (also known as programs, software, software applications, and/or code) comprise machine-readable instructions for a programmable processor, and can be implemented in a high-level procedural and/or object-oriented programming language, and/or in assembly/machine language. As used herein, the terms “machine-readable medium” and/or “computer-readable medium” refers to any computer program product, apparatus and/or device (e.g., magnetic discs, optical disks, memory, and/or Programmable Logic Devices (“PLDs”)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here may be implemented on a computing device having a display device (e.g., a cathode ray tube (“CRT”) and/or liquid crystal (“LCD”) monitor) for displaying information to the user and a keyboard and a mouse by which the user can provide input to the computer. Other kinds of devices can be used to provide for interaction with a user as well; for example, feedback provided to the user can be any form of sensory feedback (e.g., visual feedback, auditory feedback, and/or tactile feedback) and input from the user can be received in any form, including acoustic, speech, and/or tactile input.

The systems and techniques described here may be implemented in a computing system that includes a back-end component (e.g., as a data server), a middleware component (e.g., an application server), a front-end component (e.g., a client computer having a graphical user interface, and/or a Web browser through which a user can interact with an embodiment of the systems and techniques described here), and a combination thereof. The components of the system may also be coupled through a communication network.

The communication network may include a local area network (“LAN”) and a wide area network (“WAN”) (e.g., the Internet). The computing system can include a client and a server. In an embodiment, the client and the server are remote from each other and interact through the communication network.

It will be understood that various modifications may be made without departing from the spirit and scope of the claimed invention. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It may be appreciated that the various systems, methods, and apparatus disclosed herein may be embodied in a machine-readable medium and/or a machine accessible medium compatible with a data processing system (e.g., a computer system), and/or may be performed in any order.

The structures and modules in the figures may be shown as distinct and communicating with only a few specific structures and not others. The structures may be merged with each other, may perform overlapping functions, and may communicate with other structures not shown to be connected in the figures. Accordingly, the specification and/or drawings may be regarded in an illustrative rather than a restrictive sense.

Where the above examples, embodiments and implementations reference examples, it should be understood by those of ordinary skill in the art that other methods could be intermixed or substituted with those provided. In places where the description above refers to particular methods, it should be readily apparent that a number of modifications may be made without departing from the spirit thereof and that these embodiments and implementations may be applied to other to educational technologies as well. Accordingly, the disclosed subject matter is intended to embrace all such alterations, modifications and variations that fall within the spirit and scope of the disclosure and the knowledge of one of ordinary skill in the art.

Many additional implementations are possible. Further implementations are within the CLAIMS.

I/We claim:

1. A method for creating remedial geotechnical engineering plans for a structure with a recommendation design platform, the method comprising:
receiving first data at the recommendation design platform from a first visit by a site technician to the structure, wherein the first data comprises:
first manometer readings providing first elevation measurements for a floor of the structure;
first moisture observations around a foundation of the structure;
proximity of vegetation to the structure at a time of the first visit; and
evidence of cracks in the structure at the time of the first visit;
receiving second data at the recommendation design platform from a second visit to the structure at least 1 year after the first visit, the second data comprising:
second manometer readings providing second elevation measurements for the floor of the structure;
second moisture observations around the foundation of the structure;
proximity of vegetation to the structure at a time of the second visit; and
evidence of cracks in the structure at the time of the second visit;
receiving custom third-party input at the recommendation design platform, wherein the custom third-party input comprises:
an aerial site image;
historical rainfall information;
a deflection analysis;
information from the Nuclear Regulatory Commission or the Post-Tensioning Institute; and
drone-captured lidar point cloud data;
constructing a first topographical map of the floor of the structure using the first elevation measurements;
constructing a second topographical map of the floor of the structure using the second elevation measurements;
comparing, by the recommendation design platform, the first elevation measurements for the floor of the structure and the second elevation measurements for the floor of the structure to determine soil movement over time;
creating, by the recommendation design platform, proposed remedial geotechnical engineering plans for the structure based on:
the determined soil movement over time;
the evidence of cracks in the structure at the time of the first visit and at the time of the second visit; and
the first and second moisture observations around the foundation of the structure; and
receiving, at the recommendation design platform, modifications to the proposed remedial geotechnical engineering plans from a licensed engineer to create sealed remedial geotechnical engineering plans for the structure.

2. The method of claim 1, wherein the second visit to the structure is at least 5 years after the first visit.

3. The method of claim 1, wherein the first topographical map of the floor of the structure comprises a two-dimensional topographical map.

4. The method of claim 3, further comprising constructing a three-dimensional topographical map of the floor of the structure using the first elevation measurements.

5. The method of claim 1, wherein the first topographical map of the floor of the structure comprises a three-dimensional topographical map.

6. The method of claim 1, further comprising displaying a floor plan of the structure overlaid on the first topographical map of the floor of the structure.

7. The method of claim 6, further comprising displaying a marker on the floor plan indicating a location of the evidence of cracks in the structure at the time of the first visit.

8. A method for creating remedial geotechnical engineering plans for a structure with a recommendation design platform, the method comprising:
receiving first data at the recommendation design platform from a first visit by a site technician to the structure, wherein the first data comprises first elevation measurements for a floor of the structure,
receiving second data at the recommendation design platform from a second visit to the structure after the first visit, wherein the second data comprises second elevation measurements for a floor of the structure;
receiving custom third-party input at the recommendation design platform;
comparing, by the recommendation design platform, the first elevation measurements for the floor of the structure and the second elevation measurements for the floor of the structure to determine soil movement over time;
creating, by the recommendation design platform, proposed remedial geotechnical engineering plans for the structure based on:
the determined soil movement over time,
evidence of cracks in the structure, and
moisture observations around a foundation of the structure; and
receiving, at the recommendation design platform, modifications to the proposed remedial geotechnical engineering plans from a licensed engineer to create sealed remedial geotechnical engineering plans for the structure.

9. The method of claim 8, wherein the second visit to the structure is at least 1 year after the first visit.

10. The method of claim 8, wherein the second visit to the structure is at least 5 years after the first visit.

11. The method of claim 8, further comprising:
constructing a first topographical map of the floor of the structure using the first elevation measurements; and
constructing a second topographical map of the floor of the structure using the second elevation measurements.

12. The method of claim 8, wherein the custom third-party input comprises:
an aerial site image;
historical rainfall information;
a deflection analysis;
information from the Nuclear Regulatory Commission or the Post-Tensioning Institute; and
drone-captured lidar point cloud data.

13. A system for creating remedial geotechnical engineering plans for a structure with a recommendation design platform, the system comprising:
a processor communicatively coupled to a memory and a network interface, the network interface communicatively coupled to a network;
a data manager communicatively coupled to the network interface and the network and configured to:
receive first data from a first visit to the structure through the network,
receive second data from a second visit to the structure, after the first visit, through the network, and
receive third-party data for a site of the structure, through the network; and
a model engine communicatively coupled to the data manager and an engineering interface, the model engine configured to:
create a model for the site and the structure based on the first data, second data, and third-party data, to approximate site soil movement,
create proposed remedial geotechnical engineering plans from the model and the approximated site soil movement, and
send the proposed remedial geotechnical engineering plans to the engineering interface;
wherein the engineering interface is communicatively coupled to the network interface and the network and is further configured to present the proposed remedial geotechnical engineering plans to, and receive input from, a licensed geotechnical engineer to finalize the proposed remedial geotechnical engineering plans and create final remedial geotechnical engineering plans for the structure signed by the geotechnical engineer.

14. The system of claim 13, wherein the first data is received at the data manager from a site technician.

15. The system of claim 13, wherein the second visit to the structure is at least 1 year after the first visit.

16. The system of claim 13, wherein the second visit to the structure is at least 5 years after the first visit.

17. The system of claim 13, wherein the first data comprises:
first manometer readings providing first elevation measurements for a floor of the structure;
first moisture observations around a foundation of the structure;
proximity of vegetation to the structure at a time of the first visit; and
evidence of cracks in the structure at the time of the first visit.

18. The system of claim 17, wherein the second data comprises:
second manometer readings providing second elevation measurements for the floor of the structure;
second moisture observations around a foundation of the structure;
proximity of vegetation to the structure at a time of the second visit; and
evidence of cracks in the structure at the time of the second visit.

19. The system of claim 18, wherein the model engine is configured to:
construct a first topographical map of the floor of the structure using the first elevation measurements; and
construct a second topographical map of the floor of the structure using the second elevation measurements.

20. The system of claim 13, wherein the third-party input comprises:
an aerial site image;
historical rainfall information;
deflection analysis;
information from the Nuclear Regulatory Commission or the Post-Tensioning Institute; and
drone-captured lidar point cloud data.
